(19) United States
(12) Patent Application Publication
(10) Pub. No.: US 2025/0203784 A1
(43) Pub. Date: Jun. 19, 2025

(54) Sintering Methods

(71) Applicant: Celanese Mercury Holdings Inc., Wilmington, DE (US)

(72) Inventors: Kazutaka Ozawa, Tokyo (JP); Henry Rosenfeld, Drumore, PA (US); Aya Nakamoto, Kanagawa (JP); Yushi Fukui, Kanagawa (JP)

(21) Appl. No.: 18/957,956

(22) Filed: Nov. 25, 2024

Related U.S. Application Data
(60) Provisional application No. 63/609,899, filed on Dec. 14, 2023.

(51) Int. Cl. H05K 3/32; B22F 7/06; H01L 23/00

(52) U.S. Cl. CPC H05K 3/32; B22F 7/064; H01L 24/29; H01L 24/83; B22F 2301/255; B22F 2304/056; B22F 2304/058; H01L 2224/2929; H01L 2224/29339; H01L 2224/2949; H01L 2224/8384; H05K 2203/1131

(57) ABSTRACT

A sintering method for joining at least two components is provided. The method includes disposing a conductive paste on a first component. The conductive paste includes a metal powder dispersed in an organic vehicle. The metal powder has a D50 ranging from about 200 nm to about 500 nm. The method includes drying the conductive paste to form a dried conductive paste and disposing a second component on the dried conductive paste to form a component arrangement. The method includes sintering the component arrangement without applying external pressure to the component arrangement. Electronic articles are also provided.

### RELATED APPLICATION

The present application is based upon and claims priority to U.S. Provisional Patent Application Ser. No. 63/609,899, having a filing date of Dec. 14, 2023, which is incorporated herein by reference.

### BACKGROUND OF THE DISCLOSURE

Solder connections or sintering technology are used for joining electronic components to a substrate. Sintered connections provide a sintered bond between parts having high temperature resistance while ensuring good electrical and thermal contact. However, processes for sintering electronic components together require sintering at high process temperatures and utilizing die bond equipment to pressurize the sintered arrangement, which increases manufacturing time, complexity, and cost. Additionally, sintering process that do not utilize pressure require long sintering time and it can be very difficult to control fillet thickness during sintering.

Considering this, a need exists for improved conductive sintering materials and methods for sintering at lower temperatures and pressures.

### SUMMARY OF THE DISCLOSURE

In accordance with one embodiment of the present disclosure, provided is a sintering method for joining at least two components. The method includes disposing a conductive paste on a first component. The conductive paste includes a metal powder dispersed in an organic vehicle. The metal powder has a D50 ranging from about 200 nm to about 500 nm. The method includes drying the conductive paste to form a dried conductive paste; disposing a second component on the dried conductive paste to form a component arrangement; and sintering the component arrangement without applying external pressure to the component arrangement.

In accordance with other embodiments, an electronic article including a semiconductor chip sintered to a substrate with a conductive paste is provided. The conductive paste includes a metal powder dispersed in an organic vehicle. The metal powder has a D50 ranging from about 200 nm to about 500 nm.

Other features and aspects of the present disclosure are set forth in greater detail below.

### BRIEF DESCRIPTION OF THE FIGURES

A full and enabling disclosure of the present disclosure, including the best mode thereof, directed to one of ordinary skill in the art, is set forth more particularly in the remainder of the specification, which makes reference to the appended figures in which:

FIG. 1 is a schematic view of an example method of forming a component arrangement according to one embodiment of the present disclosure; and

FIG. 2 is a flow chart of an example method of forming a component arrangement according to one embodiment of the present disclosure.

Repeat use of references characters in the present specification and drawing is intended to represent same or analogous features or elements of the disclosure.

### DETAILED DESCRIPTION

It is to be understood by one of ordinary skill in the art that the present discussion is a description of exemplary embodiments only and is not intended as limiting the broader aspects of the present disclosure.

Generally speaking, the present disclosure is directed to a sintering method for joining at least two components. The method includes disposing a conductive paste on a first component. The conductive paste includes metal particles dispersed in a solvent. The conductive paste can also include a polymer. The conductive paste is dried and, after drying, a second component is placed on the dried conductive paste. The component arrangement is sintered without application of external pressure during sintering.

Advantageously, through selective control over the particular nature of the specific concentration of the components of the conductive paste, the present inventors have discovered that the resulting conductive paste can provide an effective sintered connection between component parts even when sintered at 0 MPa. Further, utilization of the conductive paste of the present disclosure reduces the need to apply pressure during the sintering process and also provides reduced sintering times. Thus, manufacturing complexities are reduced and improved processing rates can be realized. Additionally, utilization of the method provided herein reduces fillet creation during sintering, which reduces electrical shortage between sintered components.

Various embodiments of the present disclosure will now be described in more detail.

### I. Conductive Paste

a. Conductive Material

As indicated above, the conductive paste includes a conductive material. The conductive material of the present disclosure is not subject to any special limitation as long as it does not have an adverse effect on the technical effect of the present disclosure. The conductive material can include conductive materials with an electrical conductivity of about 7.00×10⁶ Siemens(S)/m or higher at 293 Kelvin in an embodiment, about 8.50×10⁶ S/m or higher at 293 Kelvin in another embodiment, about 1.00×10⁷ S/m or higher at 293 Kelvin in another embodiment, or about 4.00×10⁷ S/m or higher at 293 Kelvin in another embodiment. The conductive material can be a metal powder selected from the group consisting of aluminum (Al, 3.64×10⁷ S/m), nickel (Ni, 1.45×10⁷ S/m), copper (Cu, 5.81×10⁷ S/m), silver (Ag, 6.17×10⁷ S/m), gold (Au, 4.17×10⁷ S/m), molybdenum (Mo, 2.10×10⁷ S/m), magnesium (Mg, 2.30×10⁷ S/m), tungsten (W, 1.82×10⁷ S/m), cobalt (Co, 1.46×10⁷ S/m), zinc (Zn, 1.64×10⁷ S/m), platinum (Pt, 9.43×10⁶ S/m), palladium (Pd, 9.5×10⁶ S/m), alloys thereof and mixtures thereof.

In embodiments, the conductive material can be silver. In the case of using silver as the conductive material, it can be in the form of silver metal, silver derivatives and/or the mixture thereof. Examples of silver derivatives include silver oxide (Ag₂O), silver salts (such as silver chloride (AgCl), silver nitrate (AgNO₃), silver acetate (AgOOCCH₃), silver trifluoroacetate (AgOOCCF₃) or silver phosphate (Ag₃PO₄), silver-coated composites having a silver layer coated on the surface or silver-based alloys or the like.

The conductive material can be in the form of a metal powder having metal particles of various shapes (for example, spherical shape, flakes, irregular form and/or the mixture thereof). In certain embodiments, the metal powder includes spherical particles. For instance, in embodiments, at least about 60% to about 100%, such as about 70% to about 90%, such as about 85% to about 100% of the metal particles are in the form of spherical particles.

The particle diameter (D50) of the metal powder can be about 200 nm to about 3500 nm in one embodiment, such as from about 250 nm to about 1,000 nm, such as from about 300 nm to about 900 nm, such as from about 450 nm to about 850 nm. Specifically, the particle diameter (D50) of the metal powder can be from about 200 nm to about 500 nm, such as from about 250 nm to about 450 nm, such as from about 300 nm to about 400 nm, such as from about 210 nm to about 360 nm. The particle diameter (D50) can be measured by laser diffraction scattering method. For instance, in an embodiment the particle diameter (D50) can be measured by laser diffraction scattering method with Microtrac model S-3500. Other instruments known to be utilized to measure the particle diameter (D50) can also be used without departing from the scope of the present disclosure. Mixtures of metals having different average particle sizes, particle size distributions or shapes, etc. can also be employed. As used herein “D50” means that 50% of the particles are smaller than the recited size and that 50% of the particles are larger than the recited size. The metal powder can have a D10 ranging from about 100 nm to about 1,000 nm, such as from about 150 nm to about 500 nm, such as from about 150 nm to about 350 nm. In embodiments, the metal powder has a D10 ranging from about 150 to about 300, such as from about 170 to about 280, such as from about 190 to about 260, such as from about 210 to about 240, such as from about 160 nm to about 240 nm. As used herein “D10” represents that 10% of the particles in the powder are smaller than the recited size. Further, the metal powder can have a D90 ranging from about 200 nm to about 2,000 nm, such as from about 350 nm to about 1,000 nm, such as from about 400 nm to about 750 nm. In embodiments, the metal powder has a D90 ranging from about 250 to about 930, such as from about 300 to about 900, such as from about 350 to about 850, such as from about 400 to about 800, such as from about 450 to about 750, such as from about 500 to about 700, such as from about 270 nm to about 570 nm. As used herein “D90” represents that 90% of the particles in the powder are smaller than the recited size.

The specific surface area (SA) of the metal powder can be about 0.5 to about 5 m²/g in one embodiment, about 1 to about 3.5 m²/g in another embodiment and about 1.5 to about 2.5 m²/g in another embodiment. In embodiments, the metal powder has a SA of from about 0.9 m²/g to about 4 m²/g, such as from about 1 m²/g to about 3 m²/g, such as from about 2.8 m²/g to about 3.8 m²/g. The specific surface area can be measured by BET method with Monosorb™ from Quantachrome Instruments Corporation.

In one embodiment of the present disclosure, the metal powder is present in an amount of about 50 wt. % to about 98 wt. % of the conductive paste, such as from about 70 wt. % to about 95 wt. %, such as from about 75 wt. % to about 85 wt. %, such as from about 85 wt. % to about 98 wt. %, such as from about 85 wt. % to about 91 wt. %.

The metal particles in the powder can be coated with any suitable surfactant. In embodiments, the metal particles are coated with a lipid, such as a fatty acid. The fatty acids can include free fatty acids, fatty acid salts, or fatty acid esters that can be branched, unbranched, saturated or unsaturated. Suitable fatty acids include, but are not limited to, oleic acid, stearic acid, lauric acid, caprylic acid, capric acid, myristic acid, palmitic acid, arachidic acid, behenic acid, lignoceric acid, cerotic acid, and combinations thereof. In other embodiments, the metal particles can be coated with an anionic surfactant. Suitable anionic surfactants include sodium lauryl sulfate, sodium laureth sulfate, ammonium lauryl sulfate, ammonium laureth sulfate, sodium stearate, potassium cocoate, and combinations thereof. The coatings disclosed herein can be disposed on the surface of the metal particles by any means known in the art.

In embodiments, the conductive material is lead-free and does not contain lead or a lead component. Specifically, the conductive material is substantially free of any lead and the derivatives thereof (for example, lead oxides, such as lead monoxide (PbO), lead dioxide (PbO₂) or lead tetroxide (Pb₃O₄), and the like).

The metal powder can have a tap density of from about 1 g/cm³ to about 7 g/cm³, such as from about 2 g/cm³ to about 5 g/cm³, such as from about 3 g/cm³ to about 4 g/cm³. The tapping density can be determined in accordance with ISO 3953:2011.

In embodiments, the conductive material can include commercially available silver powder including CR801-DF, CR801DF-045HM, CR801DF-045W, CR801-DF-045WN, CR805-045, CR901DF-03, S1804W, S18040-NM2, SF134, and SF160 available from Ames Goldsmith Corporation; DJA03N available from Toyo Chemical Co., LTD.; EA-0101, P500-1, P500-13, P543-80, P543-91, P903-2, P903-3, and P98-40 available from Metalor Technologies; P3072 FX091, and P3072 GVP097 available from DEMI Specialty Chemicals & Co.; KSN-114 TypeDP200, KSN-200 Type DP200, and KSN-200 TypeDP500 available from Osaka Soda Co., LTD.

b. Organic Vehicle

The conductive paste can include an organic vehicle. For instance, the conductive material can be mixed with the organic vehicle to form a conductive paste. The organic vehicle can be in a liquid or viscous form to facilitate mixing. Suitable organic vehicles allow the conductive material to be uniformly dispersed therein and have a proper viscosity to deliver said the conductive material to the surface of an article such as by screen printing, stencil printing or the like. The conductive paste as provided also provides a good drying rate and excellent sintered properties even when sintered without the application of external pressure during sintering.

The organic vehicle can include an organic polymer and a solvent. In other embodiments, the organic vehicle may include only a solvent and does not include an organic polymer. A variety of inert viscous materials can be used as an organic polymer. The organic polymer can be cellulosic derivatives (e.g., ethyl cellulose, methyl cellulose, ethylhydroxyethyl cellulose, etc.); phenolic resins; acrylate polymers (e.g., polymethacrylates, polymethacrylates of lower alcohol); wood rosin, acetate derivatives (e.g., monobutyl ether of ethylene glycol monoacetate); glycol derivatives (e.g., polyethylene glycol), and mixtures thereof. The organic polymer can be present in an amount of from about 0.1 wt. % to about 1.2 wt. %, such as from about 0.6 wt. % to about 1 wt. %, such as from about 0.8 wt. % to about 1 wt. % based on the total weight of the conductive paste.

The solvent can include alcohols (e.g., texanol, ester alcohol, terpineol); esters (e.g., benzoic acid esters such as dibutylphthalate, dibasic ester), glycols (e.g., butyl carbitol, dibutyl carbitol, butyl carbitol acetate, hexylene glycol); hydrocarbons or mixtures of hydrocarbons (e.g., kerosene); and mixtures thereof. The solvent is chosen in view of organic polymer solubility. The solvent can be present in an amount of about 1 wt. % to about 20 wt. %, such as from about 3 wt. % to about 18 wt. %, such as from about 6 wt. % to about 15 wt. %, such as from about 8 wt. % to about 12 wt. %, based on the total weight of the conductive paste.

The organic vehicle can optionally include an organic additive. The organic additive can be one or more of a thickener, stabilizer, viscosity modifier, surfactant, wetting agent, thixotropic agent, and other conventional additives (for example colorants, preservatives, or oxidants), etc. The amount of the organic additive depends on the desired characteristics of the resulting conductive paste. The selected additives are not subject to limitation as long as they do not adversely affect the technical effect of the present disclosure.

### II. Articles

The conductive paste can be applied to one or more components, dried, and utilized to sinter at least two components together. Notably, the conductive paste of the present disclosure can be applied to a first component, dried, and then a second component can be disposed on the dried conductive paste forming a component arrangement. The dried conductive paste can then be sintered thus forming a sintered connection between the first component and the second component. The conductive paste can be utilized in a wide array of applications (e.g., power electronics, etc.) where an electrical connection having excellent adhesion is desired as further described and illustrated in the Examples provided hereinbelow. The component arrangement can include an electronic article whereby a sintered connection is formed via the conductive paste described herein between a semiconductor chip and a substrate.

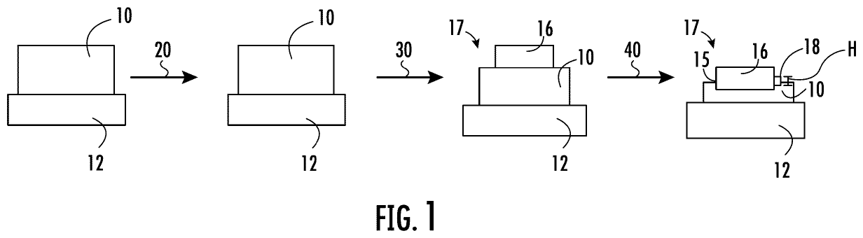

The conductive paste can be utilized to provide a sintered connection between component parts. For instance, as shown in FIG. 1, a conductive paste 10 is disposed on a substrate 12 (e.g., a first component). The substrate material can include any conductive, dielectric, or insulative material. Suitable substrates include printed circuit boards. The conductive paste 10 includes a solvent and is considered to be wet. The conductive paste 10 can be disposed on the substrate 12 via any suitable method including screen printing, stencil printing, dispense printing, or jet printing. At 20, the conductive paste 10 is dried forming a dried conductive paste 14 on the substrate 12. At 30, a second component 16 is disposed on the dried conductive paste 14. The second component 16 can include a semiconductor chip or other suitable electronic component. The substrate 12, dried conductive paste 14, and the second component 16 form a component arrangement 17 that can be sintered, at 40. Notably, the component arrangement 17 can be sintered without the application of additional external pressure being applied to the component arrangement 17. For instance, in embodiments, the component arrangement 17 can be sintered at a sintering pressure of 0 MPa. Further, in embodiments, the component arrangement can be sintered without the use of a die or other equipment and can, instead, be sintered in any suitable oven that is capable of reaching the desired sintering temperature. Further, the component arrangement 17 can be sintered at a sintering temperature ranging from about 200° C. to about 350° C., such as from about 200° C. to about 280° C., such as from about 220° C. to about 280° C. such as from about 250° C. to about 300° C., such as from about 270° C. to about 290° C.

Further, as depicted in FIG. 1, the component assembly 17 can include a fillet 18 formed from the conductive paste 10. The fillet 18 is generally formed on one or more of the sidewalls 15 of the second component 16 (e.g., semiconductor chip). The fillet 18 can have a height H generally in the vertical direction with respect to the sidewall 15 that is less than 30 μm, such as less than 20 μm, such as less than about 10 μm. For instance, in embodiments, the component assembly includes a fillet having a height of from about 1 μm to about 30 μm, such as from about 5 μm to about 25 μm, such as from about 10 μm to about 20 μm. For instance, the present inventors have discovered that use of the conductive paste of the present disclosure produces a fillet having a shorter height as compared to other wet-paste or wet processes where fillets having heights exceedingly greater than 30 μm are observed.

After sintering, the component arrangement 17 can exhibit a shear strength of at least 20 MPa to about 150 MPa, such as at least about 40 MPa to about 100 MPa, such as at least about 60 MPa to about 80 MPa, as determined with a suitable shear tester. For instance, shear strength can be measured with a Dage 4000 shear tester available from Nordson Dage in the United Kingdom. To measure shear strength, the displacement of the shearing movement is measured by a tester and the corresponding shear strength is obtained, up to the maximum shearing force at the time of shearing fracture. The corresponding displacement value is recorded. For instance, the shear strength as used herein refers to the amount of force applied to peel the sintered components apart by pushing the first and second component in lateral directions.

Further, the metal powder utilized in the conductive paste can exhibit a weight loss on ignition (e.g., Ig-loss) of less than about 2 wt. %, such as less than about 1 wt. %, such as less than about 0.8%, such as less than about 0.5%. As used herein, “weight loss on ignition” refers to the weight percentage loss of metal powder from the conductive paste upon ignition of the material. The weight loss on ignition can be determined by calculating the weight of the sample before and after it has been subjected to high temperatures. The weight loss on ignition can be calculated by dividing the weight of the sample after ignition by the pre-ignition weight and multiplying by 100.

### III. Methods

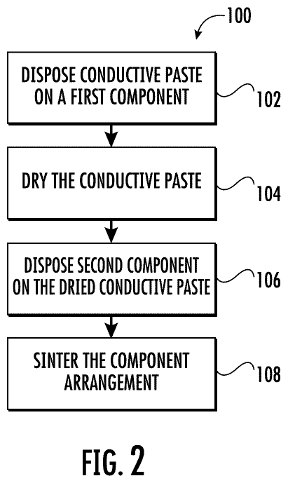

FIG. 2 depicts a flow diagram of one example method of forming an article (100) according to the present disclosure.

At (102), the method includes disposing a conductive paste on a first component. The conductive paste can include a conductive material dispersed within an organic vehicle. The conductive paste can include materials described hereinabove. In embodiments, the conductive material can include a metal powder, such as silver. The organic vehicle can include a polymer and solvent. The conductive paste can include from about 1 wt. % to about 20 wt. % of a solvent and from about 0.06 wt. % to about 0.5 wt. % of a polymer. The conductive paste can include from about 70 wt. % to about 98 wt. % of metal powder.

The conductive paste can be applied via any suitable method such as screen printing and/or stencil printing. The conductive paste can have an applied thickness of from about 75 μm to about 150 μm, such as from about 90 μm to about 120 μm, such as from about 100 μm to about 110 μm, such as from about 80 μm to about 110 μm.

At (104), the method includes drying the conductive paste prior to sintering. For instance, the conductive paste can be dried in an oven for a desired amount of time at a drying temperature. The drying temperature can range from about 80° C. to about 200° C., such as from about 100° C. to about 130° C., such as from about 110° C. to about 140° C., such as from about 80° C. to about 150° C. The drying time can also vary from about 5 minutes to about 20 minutes, such as from about 10 minutes to about 15 minutes. The drying can be completed in any suitable oven or heater.

After drying the dried conductive paste can have a thickness ranging from about 20 μm to about 80 μm, such as from about 30 μm to about 70 μm, such as from about 40 μm to about 60 μm. Notably, in embodiments, the thickness of the dried conductive paste can be reduced by at least about 25% up to about 65%, such as about 50% as compared to the applied thickness.

At (106), the method includes disposing a second component on the dried conductive paste. In such an embodiment, a die can be used to join the first component having the dried conductive paste thereon to the second component. For instance, the first component having the dried metal paste thereon can be disposed in the bottom of the die. The bottom of the die can have a temperature ranging from about 100° C. to about 175° C. The second component can be disposed in the top of the die. The top of the die can have a temperature ranging from about 150° C. to about 280° C. The top and bottom of the die can then be used to press the first component and the second component together at a pressure of about 0.1 MPa to about 10 MPa, such as from about 0.1 MPa to about 5 MPa, for a time period of about 0.1 second to about 1 minute, such as from about 1 second to about 20 seconds. The first component, dried conductive paste, and second component form a component arrangement that can then be sintered.

At (108), the method includes sintering the component arrangement. The component arrangement can be sintered at a sintering temperature ranging from about 200° C. to about 400° C., such as from about 250° C. to about 350° C., such as from about 250° C. to about 300° C. The component arrangement can be sintered for a sintering time ranging from about 5 minutes to about 120 minutes, such as from about 15 minutes to about 90 minutes, such as from about 30 minutes to about 60 minutes. The component arrangement can be sintered in air or in an inert atmosphere containing an inert gas such as nitrogen. The component arrangement can be sintered without applying any external pressure on the component arrangement during sintering. For instance, in embodiments, the component arrangement can be sintered at a sintering pressure of about 0 MPa. In other words, the sintering process does not require application of external pressure on the component arrangement as part of the sintering process. Accordingly, the component arrangement can be sintered in any oven that is capable of reaching the required sintering temperature. Advantageously, the current method allows for a more rapid sintering process that does not require additional pressure during sintering. Such a method thus reduces processing time and cost. Furthermore, no additional solvent removal steps are required during method (100).

The thickness of the sintered conductive pasted disposed between the two components can be from about 20 μm to about 60 μm, such as from about 30 μm, to about 50 μm. Notably, in embodiments, the thickness of the sintered conductive paste can be reduced by at least about 10% up to about 60%, such as from about 20% up to about 50%, as compared to the dried conductive paste thickness.

### Examples

The present disclosure is further illustrated by, but is not limited to, the following examples.

The example conductive pastes were prepared by dispersing various silver powders in a mixture of an organic solvent and a polymer. The dispersion was carried out by mixing the components in a mixer followed by a three-roll mill.

Examples and Comparative Examples sintered in air are illustrated in Table 1 below. For instance, Table 1 provides the D10, D50, and D90 of the metal powders utilized in each example along with the amount of metal powder, solvent, and polymer. The representative die shear strengths for each example are also provided.

TABLE 1

| | | | | | Polymer | | Die |
|---|---|---|---|---|---|---|---|
| | | | | Ag | wt. % in | | shear |
| | | | | powder/ | 10 wt. % | Solvent | strength/ |
| Example | d10/nm | d50/nm | d90/nm | wt % | solvent | wt % | MPa |
| Ex. 1 | 260 | 410 | 890 | 85.09 | 8.51 | 6.40 | 33.32 |
| Ex. 2 | 260 | 410 | 890 | 85.09 | 8.51 | 6.40 | 33.21 |
| Ex. 3 | 150 | 290 | 550 | 86.66 | 8.67 | 4.67 | 44.29 |
| Ex. 4 | 240 | 360 | 570 | 88.16 | 8.82 | 3.03 | 70.59 |
| Ex. 5 | 240 | 360 | 570 | 88.16 | 8.82 | 3.03 | 71.77 |
| Ex. 6 | 170 | 220 | 320 | 88.16 | 8.82 | 3.02 | 75.33 |
| Ex. 7 | 170 | 220 | 310 | 88.16 | 8.82 | 3.02 | 82.67 |
| Ex. 8 | 160 | 210 | 270 | 88.16 | 8.82 | 3.02 | 78.64 |
| Ex. 9 | 270 | 450 | 770 | 88.64 | 8.86 | 2.50 | 35.38 |
| Ex. 10 | 180 | 360 | 800 | 89.37 | 8.94 | 1.69 | 40.57 |
| Ex. 11 | 180 | 330 | 660 | 89.37 | 8.93 | 1.70 | 30.72 |
| Ex. 12 | 180 | 330 | 670 | 89.42 | 8.96 | 1.63 | 25.58 |
| Ex. 13 | 260 | 420 | 760 | 89.69 | 8.97 | 1.34 | 23.53 |
| Ex. 14 | 180 | 310 | 550 | 90.14 | 9.02 | 0.84 | 22.25 |
| Ex. 15 | 280 | 430 | 840 | 90.90 | 9.10 | 0.00 | 39.75 |
| Ex. 16 | 270 | 420 | 930 | 90.90 | 9.10 | 0.00 | 46.01 |
| Comp. Ex. | 1100 | 2120 | 4100 | 88.51 | 8.85 | 2.64 | 0.08 |
| 17 | | | | | | | |
| Comp. Ex. | 1320 | 2080 | 3440 | 85.21 | 8.52 | 6.27 | 0.10 |
| 18 | | | | | | | |
| Comp. Ex. | 780 | 3300 | 10800 | 88.15 | 8.82 | 3.03 | 0.14 |
| 19 | | | | | | | |
| Comp. Ex. | 1450 | 6610 | 14000 | 90.90 | 9.10 | 0.00 | 0.16 |
| 20 | | | | | | | |
| Comp. Ex. | 620 | 1750 | 3720 | 89.09 | 8.91 | 2.00 | 0.26 |
| 21 | | | | | | | |
| Comp. Ex. | 730 | 1370 | 2980 | 86.51 | 10.81 | 2.68 | 0.31 |
| 22 | | | | | | | |
| Comp. Ex. | 1200 | 3060 | 7270 | 73.13 | 25.30 | 1.57 | 0.33 |
| 23 | | | | | | | |
| Comp. Ex. | 3810 | 9130 | 20700 | 83.29 | 10.53 | 6.18 | 0.50 |
| 24 | | | | | | | |
| Comp. Ex. | 650 | 1480 | 8490 | 90.91 | 9.09 | 0.00 | 0.51 |
| 25 | | | | | | | |
| Comp. Ex. | 530 | 1400 | 7200 | 90.91 | 9.09 | 0.00 | 0.52 |
| 26 | | | | | | | |
| Comp. Ex. | 860 | 3420 | 10300 | 90.91 | 9.09 | 0.00 | 0.59 |
| 27 | | | | | | | |
| Comp. Ex. | 2700 | 7500 | 18700 | 86.96 | 8.70 | 4.34 | 0.64 |
| 28 | | | | | | | |

The example pastes were stencil printed by metal squeeze on to a substrate surface. The substrate was a copper substrate. Squares of conductive pastes were printed on the substrate having a size of 13 mm by 13 mm. The squares had an applied thickness of 100 μm. The squares were then dried at 120° C. for 10 minutes. After drying, the dried conductive paste squares had a thickness of about 60 μm. A chip was then mounted on the dried conductive paste. The chip was mounted using a die bonder having a bottom heat of 150° C. and a top heat of 175° C. The substrate having the dried conductive paste thereon was mounted into the bottom of the die bonder and the chip was mounted into the top of the die bonder. The die bonder pressed the substrate and chip together at a pressure of 1 MPa for a time period of about 10 seconds. The substrate, dried conductive paste, and chip were sintered in an air atmosphere at a sintering temperature of 290° C. at 0 MPa for a time period of 30 minutes. There was no heating ramp up. The sintered thickness of the paste was about 45 μm.

After sintering the die shear strength between the chip and the copper plate for each example was measured after thermal cycling. The testing was done in accordance with a standard die shear test method (MIL STD-883) using a bond tester (4000 Plus, Nordson Advanced Technology Co., Ltd.). The die shear strength was defined as the strength when the copper chip was peeled off by the bond tester.

As depicted, the representative examples including metal powders having D50s ranging from about 210 nm to about 450 nm, D10s ranging from about 150 nm to about 280 nm, and D90s ranging from about 270 nm to about 930 nm provided suitable shear strengths ranging from about 22 mPa to about 83 mPa. Whereas the comparative examples having D50s ranging from 1370 nm to 9130 nm, D10s ranging from 530 nm to 3180 nm, and D90s ranging from 2980 to 20,700 nm exhibited unsuitable mPa ranging from 0.08 mPa to 0.64 mPa.

Examples and Comparative Examples sintered in nitrogen are illustrated in Table 2 below. For instance, Table 2 provides the D10, D50, and D90 of the metal powders utilized in each example along with the amount of metal powder, solvent, and polymer. The representative die shear strengths for each example are also provided.

TABLE 2

| | | | | | Polymer | | Die |
|---|---|---|---|---|---|---|---|
| | | | | | wt. % in | | shear |
| | | | | Ag powder/ | 10 wt. % | Solvent | strength/ |
| Example | d10/nm | d50/nm | d90/nm | wt % | solvent | wt % | MPa |
| Ex. 1 | 170 | 230 | 340 | 88.16 | 8.82 | 3.02 | 20.9 |
| Comp. | 2300 | 6000 | 11700 | 79.14 | 11.87 | 8.99 | 14.31 |
| Ex. 1 | | | | | | | |
| Comp. | 1400 | 3600 | 8000 | 74.53 | 7.46 | 18.01 | 11.04 |
| Ex. 2 | | | | | | | |

The example pastes were stencil printed by metal squeeze on to a substrate surface. The substrate was a silver substrate. Squares of conductive pastes were printed on the substrate having a size of 13 mm by 13 mm. The squares had an applied thickness of 100 μm. The squares were then dried at 120° C. for 10 minutes. After drying, the dried conductive paste squares had a thickness of about 60 μm. A chip was then mounted on the dried conductive paste. The chip was mounted using a die bonder having a bottom heat of 150° C. and a top heat of 175° C. The substrate having the dried conductive paste thereon was mounted into the bottom of the die bonder and the chip was mounted into the top of the die bonder. The die bonder pressed the substrate and chip together at a pressure of 1 MPa for a time period of about 10 seconds. The substrate, dried conductive paste, and chip were sintered in a nitrogen atmosphere where nitrogen gas having >99.9995 vol. % purity nitrogen was introduced from a gas cylinder at 5 L/min for 3 min to remove air from the chamber by nitrogen purge prior to sintering and at 2 L/min during sintering. Initially, the sintering began at 25° C. and heat was ramped up by 0.5° C./sec and held at 280° C. for 30 minutes at 0 MPa before cooling down to 40° C. by −1° C./sec. The sintered thickness of the paste was about 45 μm.

After sintering the die shear strength between the chip and the silver plate for each example was measured after thermal cycling. The testing was done in accordance with a standard die shear test method (MIL STD-883) using a bond tester (4000 Plus, Nordson Advanced Technology Co., Ltd.). The die shear strength was defined as the strength when the copper chip was peeled off by the bond tester.

### Definitions

As used herein, ranges and amounts can be expressed as “about” a particular value or range. “About” is intended to also include the exact amount. Hence “about 5 percent” means “about 5 percent” and also “5 percent.” “About” means within typical experimental error for the application or purpose intended.

As used herein, “optional” or “optionally” means that the subsequently described event or circumstance does or does not occur, and that the description includes instances where said event or circumstance occurs and instances where it does not. For example, an optional component in a method or composition means that the component may be present or may not be present in the method or composition.

As used herein, the term “substantially free” means no more than an insignificant trace amount present and encompasses completely free (e.g., 0 molar % up to 0.01 molar %).

Chemical elements are discussed in the present disclosure using their common chemical abbreviation, such as commonly found on a periodic table of elements. For example, hydrogen is represented by its common chemical abbreviation H; helium is represented by its common chemical abbreviation He; and so forth.

All references to singular characteristics or limitations of the present disclosure shall include the corresponding plural characteristic or limitation, and vice versa, unless otherwise specified or clearly implied to the contrary by the context in which the reference is made.

The methods and compositions of the present disclosure, including components thereof, can comprise, consist of, or consist essentially of the essential elements and limitations of the disclosure described herein.

These and other modifications and variations of the present disclosure may be practiced by those of ordinary skill in the art, without departing from the spirit and scope of the present disclosure. In addition, it should be understood that aspects of the various embodiments may be interchanged both in whole or in part. Furthermore, those of ordinary skill in the art will appreciate that the foregoing description is by way of example only and is not intended to limit the disclosure so further described in such appended claims.

What is claimed is:

1. A sintering method for joining at least two components, the method comprising:
disposing a conductive paste on a first component, the conductive paste comprising:
a metal powder dispersed in an organic vehicle, the metal powder having a D50 ranging from about 200 nm to about 500 nm;
drying the conductive paste to form a dried conductive paste;
disposing a second component on the dried conductive paste to form a component arrangement; and
sintering the component arrangement without applying external pressure to the component arrangement.

2. The method of claim 1, wherein drying the conductive paste comprises exposing the conductive paste to a drying temperature of between about 80° C. and 150° C. for a time period of about 1 minute to about 60 minutes.

3. The method of claim 1, wherein disposing the conductive paste on the first component comprises printing the conductive paste on the first component.

4. The method of claim 1, wherein disposing a second component on the dried metal paste comprises disposing the first component having the dried metal paste thereon on a bottom of a die, the bottom of the die having a temperature ranging from about 125° C. to about 200° C.; disposing the second component on a top of the die, the top of the die having a temperature ranging from about 150° C. to about 225° C.; and pressing the first component and second component together at a pressure of about 0.1 MPa to about 10 MPa for a time period of about 0.1 seconds to about 20 seconds.

5. The method of claim 1, wherein sintering the component arrangement comprises exposing the component arrangement to a sintering temperature ranging from about 200° C. to about 300° C. for a sintering time of about 1 minute to about 120 minutes.

6. The method of claim 1, wherein the component arrangement exhibits a shear strength of at least about 10 MPa to about 150 MPa.

7. The method of claim 1, wherein particles in the metal powder contain a coating.

8. The method of claim 7, wherein the coating comprises one or more lipids.

9. The method of claim 8, wherein the one or more lipids comprise one or more fatty acids.

10. The method of claim 1, wherein the metal powder comprises a D90 of from about 250 nm to about 930 nm.

11. The method of claim 1, wherein the metal powder comprises a D10 of from about 150 nm to about 300 nm.

12. The method of claim 1, wherein the metal powder comprises silver.

13. The method of claim 1, wherein at least 60% of the metal powder comprises spherical particles.

14. The method of claim 1, wherein after sintering, the metal powder has an Ig-loss of from about 0.5% to about 0.75%.

15. The method of claim 1, wherein after sintering, a fillet is formed on a sidewall of the chip from the conductive paste, wherein the fillet has a height of less than about 30 μm.

16. The method of claim 1, wherein the organic vehicle comprises a solvent and a polymer.

17. The method of claim 15, wherein the conductive paste comprises from about 1 wt. % to about 20 wt. % of solvent.

18. The method of claim 15, wherein the conductive paste comprises from about 0.6 wt. % to about 1 wt. % of the polymer.

19. The method of claim 1, wherein the conductive paste comprises from about 70 wt. % to about 98 wt. % of the conductive material.

20. An electronic article comprising a semiconductor chip sintered to a substrate with a conductive paste comprising a metal powder dispersed in an organic vehicle, the metal powder having a D50 ranging from about 200 nm to about 500 nm.
